(19) United States
(12) Patent Application Publication
(10) Pub. No.: US 2011/0063909 A1
(43) Pub. Date: Mar. 17, 2011

(54) NONVOLATILE SEMICONDUCTOR MEMORY AND METHOD OF TESTING THE SAME

(75) Inventor: Yukio KOMATSU, Kanagawa-ken (JP)

(73) Assignee: KABUSHIKI KAISHA TOSHIBA, Tokyo (JP)

(21) Appl. No.: 12/713,674

(22) Filed: Feb. 26, 2010

(30) Foreign Application Priority Data
Sep. 16, 2009 (JP) 2009-213989

(51) Int. Cl. G11C 16/06; G11C 16/04; G11C 29/00

(52) U.S. Cl. 365/185.09; 365/185.11; 365/201; 365/200

(57) ABSTRACT

A memory cell array and a peripheral circuit are provided. The memory cell array has a plurality of blocks which are erasing units respectively. Each of the blocks includes a plurality of memory cells. A block control unit operates according to input signals from outside and controls operation of the blocks. A ready/busy control circuit outputs a busy signal during a period of operation implementation for a block selected from the blocks, in response to an output from the block control unit. The ready/busy control circuit outputs a ready signal out of the period of the operation implementation for the selected block. A registration control unit registers the selected block as a bad block, in the case that the ready/busy control circuit outputs a busy signal when the registration control unit receives a bad block identification command.

### CROSS REFERENCE TO RELATED APPLICATION

This application is based upon and claims the benefit of priority from the prior Japanese Patent Application No. 2009-213989, filed on Sep. 16, 2009, the entire contents of which are incorporated herein by reference.

### FIELD OF THE INVENTION

The invention relates to a nonvolatile semiconductor memory and to a method of testing the nonvolatile semiconductor memory.

### DESCRIPTION OF THE BACKGROUND

In recent years, NAND flash memories, which have large capacities but are not expensive, have been employed more and more as the secondary storage devices of laptop personal computers (PCs) and the like.

As capacities of memories such as NAND flash memories become larger, more time and higher costs tend to be needed for testing the memories before shipment. What is needed accordingly is a testing apparatus capable of solving such problems.

Japanese Patent Application Publication “JP2009-76125” discloses a semiconductor testing apparatus to test a device to be tested. According to the apparatus, it is identified in each block of the device whether command receiving is impossible. When the number of identifications that command receiving is impossible reaches or exceeds a preset value in a block under testing, the apparatus excludes the block for further testing. The number is referred to as “unmatch score”.

With the above operation, it can be resumed earlier that command signals are applied to the device to be tested so as to test the other blocks.

Japanese Patent Application Publication “JP2008-287813” discloses an IC testing apparatus. The apparatus identifies a block as a bad block mandatorily when the unmatch score of addresses reaches a predetermined value with respect to the block.

Further, Japanese Patent Application Publication “JP2008-16113” discloses an IC testing apparatus. The apparatus outputs a signal indicating that the block is excluded from the testing targets, mandatorily, when the number of unmatch occurrences reaches a predetermined value with respect to the block under testing.

### SUMMARY OF INVENTION

An aspect of the present invention provides a nonvolatile semiconductor memory which is provided with a memory cell array having a plurality of blocks which are erasing units respectively, each of the blocks including a plurality of memory cells, and a peripheral circuit having a block control unit, the block control unit operating according to input signals from outside and controlling operation of the blocks. The peripheral circuit further includes a ready/busy control circuit which, in response to an output from the block control unit, outputs a busy signal during a period of operation implementation for a block selected from the blocks and which outputs a ready signal out of the period of the operation implementation for the selected block, and a registration control unit which registers the selected block as a bad block, in the case that the ready/busy control circuit outputs a busy signal when the registration control unit receives a bad block identification command.

Another aspect of the present invention provides a method of testing a nonvolatile semiconductor memory, which is provided with a memory cell array having a plurality of blocks as erasing units including a plurality of memory cells respectively, and a peripheral circuit having a block control unit which operates according to input signals from outside and which controls operation of the blocks. The method of testing the nonvolatile semiconductor memory includes inputting an operation implementation command to execute operation for a block selected from the blocks of the nonvolatile semiconductor memory, inputting a bad block identification command to the nonvolatile semiconductor memory after the operation implementation command is inputted, and identifying whether the interior of the nonvolatile semiconductor memory is in a ready state or in a busy state, and registering the selected block as a bad block in the case that the interior of the nonvolatile semiconductor memory is identified as in a busy state.

### BRIEF DESCRIPTION OF THE DRAWINGS

FIG. 1 is a block diagram illustrating connecting relationships between a NAND flash memory and a flash controller according to an embodiment of the invention.

FIG. 2 is a block diagram illustrating an example of a functional configuration of the NAND flash memory.

FIG. 3 is a waveform chart to explain a bad block identification command.

FIG. 4 is a flowchart illustrating an operation of registering a bad block.

FIG. 5 is a waveform chart to explain an example of an internal operation of the NAND flash memory.

FIG. 6 is a waveform chart illustrating examples of behaviors of a ready/busy terminal and an I/O terminal in a case where a programming command is inputted.

FIG. 7 is a table illustrating results obtained by a simultaneous measurement testing of programming time.

### DETAILED DESCRIPTION OF THE INVENTION

As the design rules for NAND flash memories have become focusing on more miniaturized NAND flash memories, greater ununiformity of memory cells tends to be observed within a single wafer or even within a chip. With increase of ununiformity of memory cells, variations in speeds of programming, reading and erasing NAND flash memories tend to become greater among chips or blocks.

Higher performance, i.e., higher data transfer speed, is required for a NAND flash memory. For example, improvement in data transfer speed is an necessary condition to secure an advantage over hard disk drives (HDDs), in large-capacity storage devices such as solid state drives (SSDs) which are expected to have large future demands.

In order to achieve higher performance required for a NAND flash memory chip, presence of a bad block is unfavorable in the chip. The bad block show characteristics which fail to meet required specifications. Accordingly, such a bad block is screened in a chip in a test before shipment from a factory. The screened bad block is registered or marked as a bad block in the chip. Marking of the bad block allows a system employed on a user side to exclude the bad block from target blocks to be used.

The specifications are defined, for example, as upper limit values of time lengths needed to program, read and erase a predetermined data unit. As for programming operation, registration of a bad block is performed as follows. A sequence of programming commands is inputted into the NAND flash memory. Subsequently, data programming is performed in a page whose address is designated. If a busy time exceeds an upper limit value, a block including the page is registered as a bad block. The busy time is defined as a time length from start of inputting the sequence of the programming commands to end of data programming which allows next input of commands.

Methods of measuring a busy time in a testing process before shipment are roughly grouped into the following two kinds.

(1) Monitoring a ready/busy terminal (hereinafter, referred to as “R/B terminal”) directly to observe a ready/busy signal (hereinafter, referred to as “R/B signal”)

(2) Inputting a status reading command

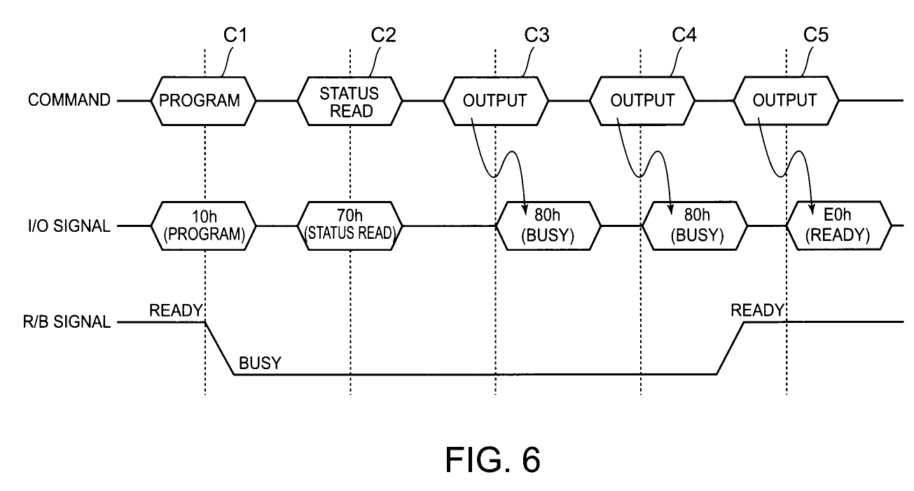

FIG. 6 is a waveform chart illustrating behaviors of a R/B signal of a R/B terminal and an I/O signal of an I/O terminal of a NAND flash memory, which receives inputs of commands C1 to C5. In FIG. 6, the commands C1 to C5 are signals being inputted through the I/O terminal. The letter “h” is added to signify that the numeral strings before “h”s express a hexadecimal number. When the R/B signal is in a “high” state, the R/B signal is defined to represent the “ready” status. When the R/B signal is in a “low” state, the R/B signal is defined to represent the “busy” status.

A data input command, an address, and data are inputted into the interior of the NAND flash memory through the I/O terminal, and then a program command C1 of “10h” is inputted. Upon the input of the program command C1, programming of data is started in a page, whose address is designated, so that the state of the R/B terminal transits from a high state to a low state. The transition causes the NAND flash memory to be in a busy state. While in the busy state, the NAND flash memory does not receive an input of a subsequent command of any kind, i.e., programming, reading or erasing command, and the NAND flash memory does not execute an internal operation indicated by the subsequent command.

Then, a status read command C2 of “70h” is inputted into the NAND flash memory through the I/O terminal of the NAND flash memory. The NAND flash memory is designed to receive the status read command C2 even while in the busy state. Upon receiving the input of the status read command C2, the NAND flash memory outputs ready/busy information through a predetermined I/O terminal. The ready/busy information outputted through the I/O terminal corresponds to the signal level of the R/B terminal.

While the NAND flash memory executes the data programming in the page whose address is specified, that is, while the R/B terminal is in the low state, the NAND flash memory outputs commands C3 and C4 in response to the status read command C2. Each of the output commands C3 and C4 is a command of “80h” signifying “busy.” In contrast, once the data programming performed in the page, whose address is designated, is finished, and the NAND flash memory has become capable of receiving input of a subsequent command, that is, while the R/B terminal is in a high state, the NAND flash memory outputs a command C5 to respond to the status read command C2. The output command C5 is a command of “E0h” signifying “ready.”

In order to measure the busy time by any one of the above-mentioned two methods (1) and (2), either the I/O terminal or the R/B terminal needs to be connected to a tester. In the testing process of NAND flash memories, plural chip areas formed on a wafer are simultaneously subjected to the busy-time measurement by probing. In this case, the tester executes pass/fail identification in the busy state for each chip. A NAND flash memory can not be shipped until all blocks that fail to meet the specifications are marked as bad blocks.

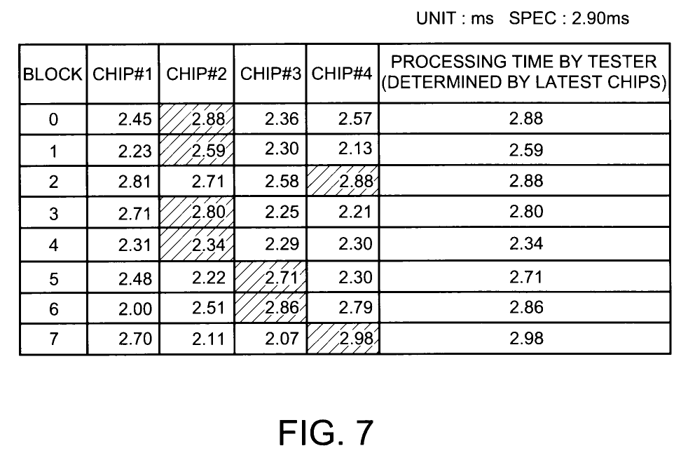

FIG. 7 is a table illustrating results obtained by a testing in which programming times of four chips #1 to #4 are simultaneously measured. Each of the chips #1 to #4 has eight blocks that are referred to as “blocks 0 to 7”. The programming times, i.e., the busy times, are simultaneously measured for the pages belonging to the blocks of the same block number. The table of FIG. 7 shows the measurement results. The upper limit value of the programming time in the specifications is 2.90 ms. Every block that has a value of busy time exceeding the upper limit value should be registered as a bad block.

For example, the measurement result for the block 0 of the chip #1 is 2.45 ms, that of the chip #2 is 2.88 ms, that of the chip #3 is 2.36 ms, and that of the chip #4 is 2.57 ms. The testing of the blocks 1 cannot be started until the measurement of the busy times for the blocks 0 of all the chips #1 to #4 is finished. Accordingly, the processing time performed by the tester depends on the chip that has the slowest programming speed. Concerning the blocks 0, the longest busy time 2.88 ms is marked by the chip #2. Thus, the testing of the blocks 1 can be started only after at least the 2.88-ms time has elapsed.

If one or more of the target blocks for the simultaneous measurement fail to meet the specifications, e.g., the block 7 of the chip #4 fails to meet the specifications, the increase in the processing time becomes much more. In addition, the NAND memory does not receive inputs of any commands other than the status read command until the R/B terminal restores a high state. Thus, a wait time, which is required until the measurement of the subsequent blocks can be started, has to be estimated to be longer.

Moreover, when one or more of the target blocks for the simultaneous measurement fail to meet the specifications and make the R/B terminal fixed to the low state disabling the R/B terminal to restore the high state, the testing cannot be conducted properly from then on. Accordingly, even a chip, which has bad blocks that are so few as to be within an allowable range, may be treated as a defective product.

As mentioned above, the capacities of NAND memories become larger and larger. Any chip cannot be shipped from a factory until all the blocks of each chip are checked concerning whether a programming time tPROG, a reading time tREAD and an erasing time tERASE meet the specifications or not. All the blocks that fail to meet the specifications are then marked as bad blocks. Accordingly, the testing requires a lot more time. The time consuming testing may be replaced by a testing where only a limited number of blocks are checked. But, such a testing may be difficult to guarantee a certain data transfer speed for the chip.

Accordingly, in order to guarantee a desired data transfer speed, i.e., performance, an efficient and precise testing has to be conducted for all the blocks included in each NAND flash memory. In addition, before the shipment of the NAND flash memory, all the blocks that fail to meet the specifications have to be marked as bad blocks. Such a requirement exists not only in the case of the above-described SDDs but also in the case of such devices as SD cards which guarantees certain data transfer speeds under the name of the “speed classes.”

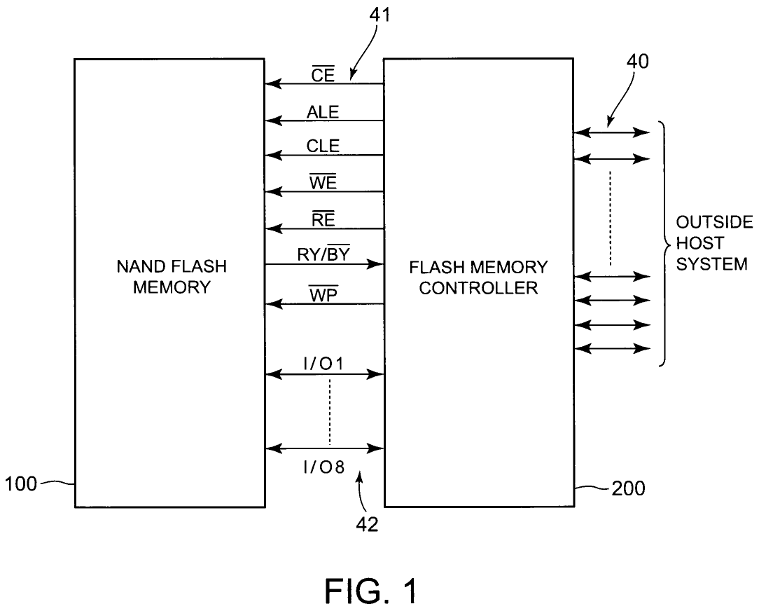

Hereinafter, a nonvolatile semiconductor memory according to an embodiment of the invention will be described with reference to the drawings. In the drawings, the same reference numerals represent the same or similar portions, respectively. A NAND flash memory is shown as an example of a nonvolatile semiconductor memory in the embodiment. FIG. 1 is a block diagram illustrating the connection relationships of the NAND flash memory and a flash controller.

As shown in FIG. 1, a NAND flash memory 100 is controlled by a flash controller 200.

The flash controller 200 is connected to an external host system (not illustrated) by means of signal lines 40. The NAND flash memory 100 is controlled by commands received from the external host system through the signal lines 40.

The NAND flash memory 100 is connected to the flash controller 200 by means of seven signal lines 41 and eight input/output lines 42. Various kinds of control signals are sent from the flash controller 200 to the NAND flash memory 100 through the signal lines 41. Such control signals are chip enable signals CE, address latch enable signals ALE, command latch enable signals CLE, write enable signals WE, read enable signals RE, and write protect signals WP. In addition, ready/busy signals R/B are sent from the NAND flash memory 100 to the flash controller 200.

Input/output signals I/O1 to I/O8 are exchanged between the flash controller 200 and the NAND flash memory 100 through the input/output lines 42. The eight input/output lines 42 may be replaced by sixteen signal lines.

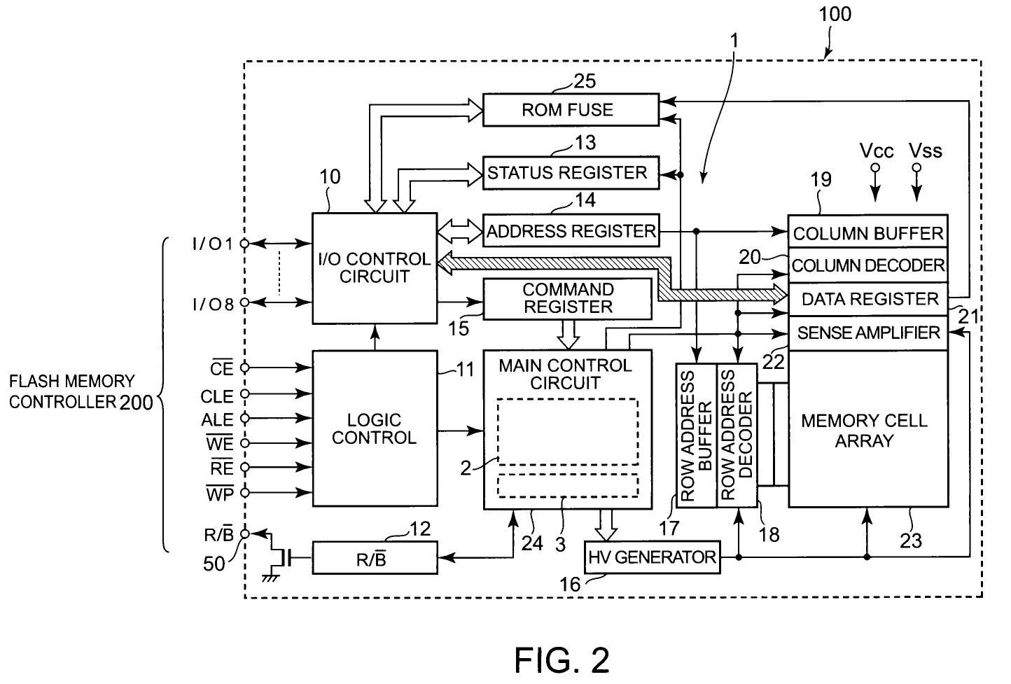

FIG. 2 is a block diagram illustrating the functional configuration of the NAND flash memory 100. The NAND flash memory 100 includes a memory cell array 23 to store data. The NAND flash memory 100 also includes various circuit elements forming a peripheral circuit 1. The circuit elements of the peripheral circuit 1 are an input/output control circuit 10, a logic control circuit 11, a ready/busy control circuit 12, a status register 13, an address register 14, a command register 15, a high voltage generator 16, a row address buffer 17, a row address decoder 18, a column address buffer 19, a column decoder 20, a data register 21, a sense amplifier 22, a main control circuit 24, and a ROM fuse 25.

The input/output control circuit 10 controls the transfer of commands and addresses as the input/output signals I/O1 to I/O8, which are inputted or outputted through the input/output lines 42. In addition, the input/output control circuit 10 controls the input and the output of data through the input/output lines 42. Some of the commands to be inputted into the NAND flash memory 100 are programming commands, reading commands, erasing commands, status read commands, and bad block identification commands, for example. Detailed description of the bad block identification will be given below.

The logic control circuit 11 receives the various controlling signals that are inputted from the flash controller 200. The logic control circuit 11 combines the signals to control the input/output control circuit 10 and the main control circuit 24. The main control circuit 24 includes a block control unit 2. In accordance with the inputted commands, the block control unit 2 controls the ready/busy control circuit 12, the status register 13, the high voltage generator 16, the row address buffer 17, the row address decoder 18, the column address buffer 19, the column decoder 20, the data register 21, the sense amplifier 22, and the ROM fuse 25 to program data into, read data from, or erase data in the blocks of the memory cell array 23.

In accordance with the operation state of the main control circuit 24, that is in accordance with whether the programming, the reading or the erasing is performed or not, the ready/busy control circuit 12 outputs the ready/busy signals R/B through an R/B terminal 50. For example, while the NAND flash memory 100 is performing an internal operation such as the programming, the reading, or the erasing of data, the signal level of the R/B terminal 50 is low. In contrast, once the internal operation is finished, the signal level of the R/B terminal 50 becomes high.

At the time of booting the NAND flash memory 100, that is, at the time of power-on reading, the status register 13 fetches various kinds of parameter information stored in the ROM fuse 25 and holds the fetched information temporarily.

The address register 14 holds the addresses having been inputted from the flash controller 200 through the input/output control circuit 10, temporarily. The address register 14, then, transfers the addresses to the row address buffer 17 and the column address buffer 19.

The command register 15 holds the commands having been inputted from the flash controller 200 through the input/output control circuit 10, temporarily. The command register 15, then, transfers the commands to the main control circuit 24. The commands is the programming commands, the reading commands, the erasing commands, the status read commands, and the like.

In accordance with the state of the main control circuit 24, the high voltage generator 16 generates high voltages needed to perform such operations as the programming, the reading and the erasing of data. The high voltage generator 16 supplies the high voltages to the row address decoder 18, the sense amplifier 22 and the memory cell array 23.

The row address buffer 17 holds the row addresses inputted from the address register 14 temporarily, and transfers the row addresses to the row address decoder 18.

In accordance with the row addresses inputted from the row address buffer 17, the row address decoder 18 controls the word lines. The row address decoder 18 applies voltages to the word lines selectively when an operation of programming or reading data is performed.

The column address buffer 19 holds the column addresses inputted from the address register 14 temporarily, and transfers the column addresses to the column decoder 20.

In accordance with the column addresses inputted from the column address buffer 19, the column decoder 20 controls the bit lines. The column decoder 20 applies voltages to the bit lines selectively when an operation of programming or reading data is performed.

The data register 21 holds a certain amount of programming data inputted from the input/output control circuit 10 or a certain amount of reading data having been acquired from the sense amplifier 22, temporarily.

The sense amplifier 22 senses and then amplifies the “1s” and the “0s” of the data read from the memory cell array 23. The sense amplifier 22 includes sense amplifier circuits corresponding respectively to the bit lines, for example.

The memory cell array 23 has a structure including plural memory cell transistors arranged in a matrix shape. The memory cell transistors hold either multiple-value data or binary data by means of the differences in the threshold voltage of the memory cell transistors. The threshold voltage is determined by the amount of charges accumulated in the floating gate of each memory cell transistor. Each memory cell transistor may be one having a MONOS structure in which charges are captured in a nitride film serving as a charge storage layer.

The memory cell array 23 includes plural blocks. Each of the blocks is formed by a part of the memory cell array 23, and functions as an erasing unit. Each block includes plural pages each functioning as a programming unit and a reading unit. Each page is defined as a group of memory cells that are commonly connected to a single one of the word lines, for example.

The main control circuit 24 of the NAND flash memory 100 according to the embodiment includes a registration control unit 3 to perform operations of registering bad blocks. The registration control unit 3 permits inputs of bad block identification commands into the NAND flash memory 100 irrespective of whether the NAND flash memory 100 is in the ready state or in the busy state. In addition, while the internal operation of the selected ones of all the blocks of the memory cell array 23 is being executed, that is, while the NAND flash memory 100 is in the busy state, the registration control unit 3 of the main control circuit 24 registers the selected block as a bad block. In order to avoid any erroneous operation of the NAND flash memory 100 while the user uses the NAND flash memory 100 under ordinary conditions, the inputting of the bad block identification commands is permitted only on condition that the NAND flash memory 100 is in the test mode.

The operation of registering bad blocks using bad block identification commands may be performed by the tester in the testing process before shipment. Alternatively, the operation of registering bad blocks may be performed by the flash controller 200 after the flash controller 200 sends a command to make the NAND flash memory 100 transition to the test mode. To be more specific, the flash controller 200 may perform the operation of registering bad blocks when the NAND flash memory 100 is booted or at an arbitrary timing. Upon receiving the bad block identification command, the main control circuit 24 works together with other functional portions so as to perform the operation of registering bad blocks. Alternatively, a self-testing circuit may perform the operation of registering bad blocks. Detailed description of the registration operation will be given below.

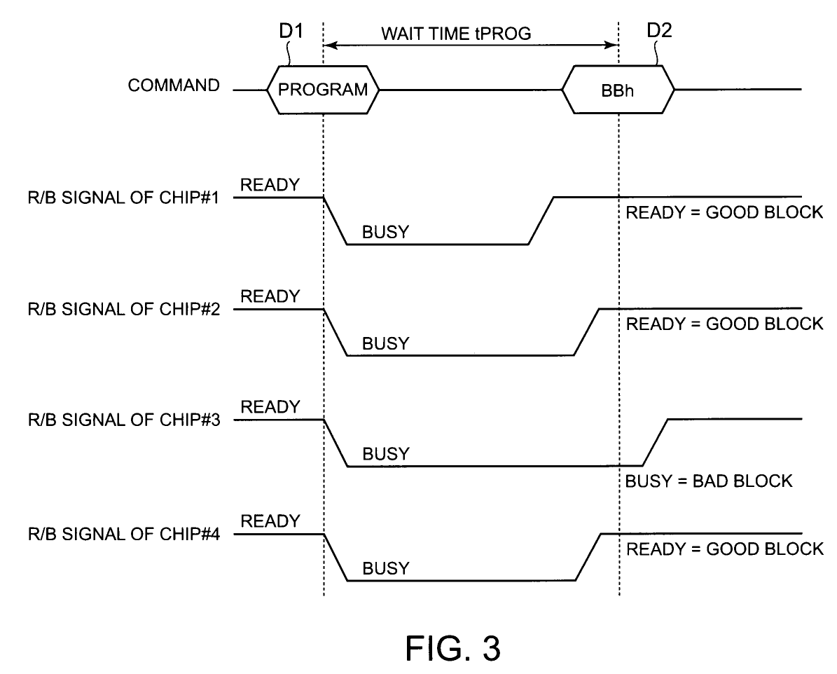

FIG. 3 is a waveform chart explaining the bad block identification command. Specifically, FIG. 3 illustrates commands inputted commonly into the four chips #1 to #4 and the signal levels of the R/B terminals 50 of the chips #1 to #4. Firstly, when a programming command D1 is inputted into each of the chips #1 to #4, the ready/busy control circuit 12 shown in FIG. 2 makes the signal level of the R/B terminals 50 of each NAND flash memory 100 transition from the high state to the low state. While each NAND flash memory 100 is in the busy state, data is being programmed into a page whose address is specified within each of the chips #1 to #4.

Subsequently, a bad block identification command D2 having a value of “BBh” is inputted into each of the chips #1 to #4 after a predetermine wait time, that is, the upper limit value of the programming time tPROG) defined in the specifications, is elapsed. The value “BBh” used as the bad block identification command D2 is only an example. Any value other than the values already assigned to the other commands may be used for this purpose. Upon receiving the bad block identification command D2, the registration control unit 3 of the main control circuit 24 of each of the chips #1 to #4 executes a predetermined internal operation to register the block that fails to meet the specifications as a bad block. Detailed description of the predetermined internal operation will be given below. Subsequently, the ready/busy control circuit 12 makes the R/B terminal 50 transition mandatorily to the high state.

For example, in the case of each of the chips #1, #2, and #4, the R/B terminal 50 is in the high state, that is, the NAND flash memory 100 is in the ready state, at the time when the bad block identification command D2 is inputted after the wait time tPROG is elapsed. Accordingly, the main control circuit 24 of each of the chips #1, #2, and #4, does not execute the operation of registering the bad block. In contrast, in the case of the chip #3, the R/B terminal 50 is in the low state, that is, the NAND flash memory 100 is in the busy state, at the time when the bad block identification command D2 is inputted after the wait time tPROG has elapsed. Accordingly, the main control circuit 24 of the chip #3 will register the selected block including the page of the programming target as a bad block.

The method of registering or marking the selected block as a bad block is not limited to a specific method. For example, a block decoder in the row address decoder 18 shown in FIG. 2 is electrically processed to make the block unable to be selected or unselected. Alternatively, flag data indicating a bad block are programmed into a predetermined page within the selected block to make the system side including the flash controller 200 not use the block indicated by the flag data. A specific method of electrically processing the block decoder is described in Japanese Patent Application Publication “JP2002-117699” of the same applicants, which corresponds to United State Patent Application Publication “US2002-0048191”.

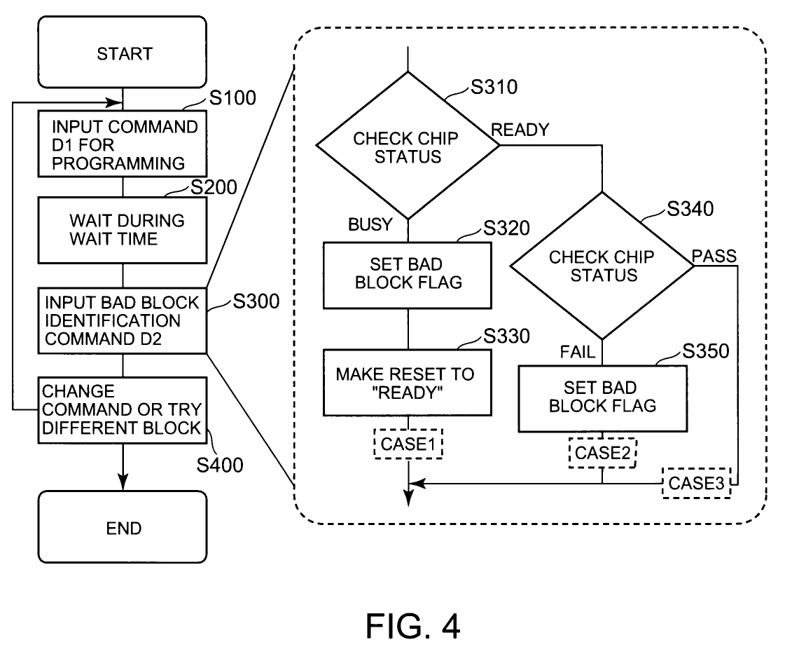

FIG. 4 is a flowchart illustrating, in detail, the operation of registering bad blocks performed by the main control circuit 24 shown in FIG. 2. As is described above, the main control circuit 24 includes the registration control unit 3 to perform the operation of registering bad blocks. In order to control the NAND flash memory 100, either the tester or the flash controller 200 can be used. The following description is based on an example where the flash controller 200 is used for the purpose. The flash controller 200 inputs a command D1 into the NAND flash memory 100 through the I/O terminal of the NAND flash memory 100. The command D1 may be a programming command, a reading command or an erasing command. In the example shown in FIG. 4, a programming command is inputted as an example of the command D1 (step S100).

In accordance with the kind of the command D1 inputted at step S100, the flash controller 200 waits for a time period defined by the specifications (step S200). Specifically, if the inputted command D1 is a programming command, the flash controller 200 waits for the upper limit value of the programming time (tPROG) after the input of the command D1. If the inputted command D1 is a reading command, the flash controller 200 waits for the upper limit value of the reading time tREAD after the input of the command D1. If the inputted command D1 is an erasing command, the flash controller 200 waits for the upper limit value of the erasing time tERASE after the input of the command D1.

Once the wait time defined for the command of each kind is elapsed, the flash controller 200 inputs a bad block identification command D2 into the NAND flash memory 100 through the I/O terminal of the NAND flash memory 100. When the bad block identification command D2 is inputted, the signal level of the R/B terminal 50 of the NAND flash memory 100 may be either in the high state or in the low state. Upon receiving the input of the bad block identification command D2, the main control circuit 24 executes an identification of whether the selected block is good or bad (step S300).

Once the testing is completed, based on the command D1 inputted at step S100, for all the blocks of the testing target within the chip, the process at S100 is performed (step S400). This time, however, the process at step S100 is performed based on a command of any other kind.

If the testing is not completed, based on the command D1 inputted at step S100, yet for all the blocks of the testing target within the chip, the process at S100 is performed to test a different block (step S400). At the time, however, the process at step S100 is based on the same command D1. Once the testing is completed, based on the command of all kinds registered as the testing items, on all the blocks, the series of processes are finished.

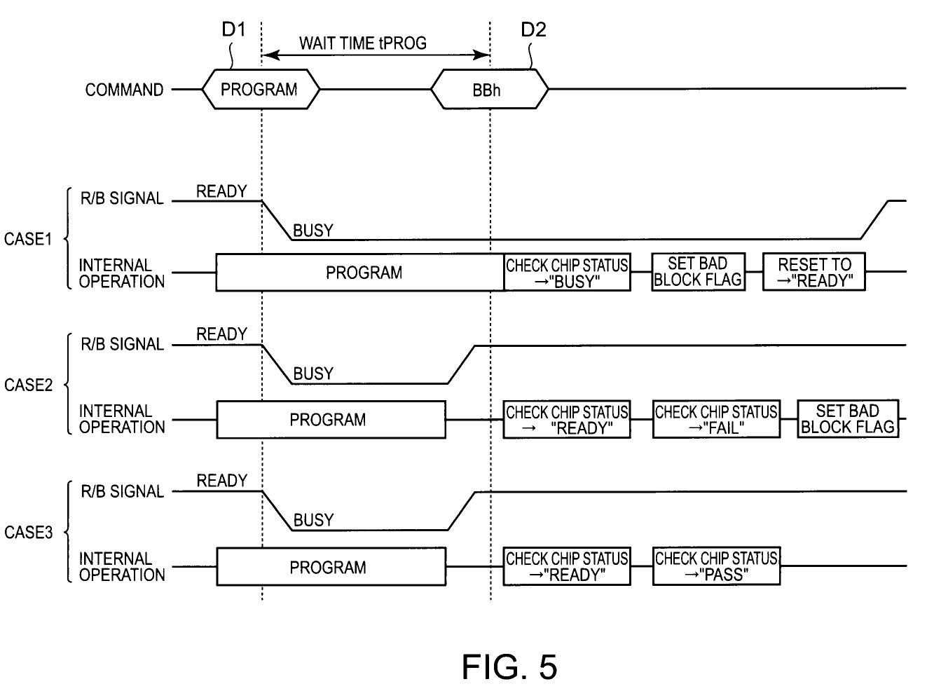

The identification performed at step S300 will be described with reference to both to the operational flow provided on the right-hand side in FIG. 4 and to FIG. 5. The identification concerns whether the selected block is good or bad. The operational flow on the right-hand side in FIG. 4 corresponds to the process at step S300 of FIG. 4. FIG. 5 is a waveform chart explaining the internal operation of the NAND flash memory 100 performed upon receiving the bad block identification command D1. The “case 1” to the “case 3” put in FIG. 5 correspond respectively to the “case 1” to the “case 3” each shown by rectangles indicated by dashed lines in the right-hand side operational flow of FIG. 4.

As FIG. 4 shows, when the NAND flash memory 100 receives the bad block identification command D1, the main control circuit 24 identifies whether the internal operation of the chip is executed or the internal operation of the chip is finished to leave the chip capable of receiving the subsequent command, based on the output signal from the ready/busy control circuit 12 (step S310). In other words, the main control circuit 24 identifies whether the chip is in the busy state or in the ready state.

If the chip is identified as being in the busy state at step S310, the main control circuit 24 registers the selected block that is the target of the internal operation, as a bad block. To perform the registration, the main control circuit 24 electrically processes the block decoder provided in the row address decoder 18 and corresponding to the selected block. The electrical processing makes the selected block unselectable (step S320).

After the main control circuit 24 registers the selected block as a bad block, the main control circuit 24 works together with the ready/busy control circuit 12 to make the R/B terminal 50 transition mandatorily to the high state (step S330).

The case 1 of FIG. 5 shows the operational flow of the internal operation performed at steps S320 and S330 if the chip has been identified as being in the busy state at step S310. The case 1 corresponds to the following case, for example. After the input of a programming command, the programming of data into a page whose address is specified takes so long a time that the busy time cannot meet the specification and, at the same time, the signal level of the R/B terminal 50 is fixed to the low state.

On the other hand, if the chip is identified as being in the ready state at step S310, the main control circuit 24 identifies whether the NAND flash memory 100 has completed properly the internal operation corresponding to the command having been inputted at step S100 or has failed to complete properly the internal operation (step S340). The proper or normal completion of the internal operation will be referred to as “Pass” whereas the improper or abnormal completion of the internal operation will be referred to as “Fail.” The need for such identification comes from the possibility of a case where, even if the busy time meets the specifications, the operation of programming, reading, or erasing data can faile to be completed properly.

The Pass/Fail information obtained at step S340 has the same content as the information outputted through a predetermined terminal of the NAND flash memory 100 other than the terminal to output the ready/busy information when a status read command is inputted. The Pass/Fail information is held in the register, when the internal operation of the NAND flash memory 100 is finished, for example.

If the internal operation is identified as “Fail” at step S310, the NAND flash memory 100 registers the selected block as a bad block (S350).

The case 2 of FIG. 5 shows the operational flow of the internal operation performed at step S350 if the chip has been identified as being in the ready state at step S310 and then the internal operation is identified as “Fail” at step S340. The case 2 corresponds to the following case, for example. After the input of a programming command, the programming of data into a page, whose address is specified, fails to be completed properly so that the signal level of the R/B terminal 50 is restored to the high state.

In contrast, if the internal operation is identified as “Pass” at step S340, the selected block meets the specification and the internal operation has been completed properly. The main control circuit 24 does not register the selected block as a bad block and the operational flow proceeds to step S400 described above.

The case 3 of FIG. 5 shows the operational flow of the internal operation performed if the chip has been identified as being in the ready state at step S310 and then the internal operation is identified as “Pass” at step S340. The case 3 corresponds to the following case, for example. After the input of a programming command into the NAND flash memory 100, the programming of data into a page, whose address is specified, is completed properly so that the signal level of the R/B terminal 50 is restored to the high state.

According to the NAND flash memory and the method of testing a NAND flash memory of the embodiment, the following advantages (1) to (3) can be obtained.

### (1) Guaranteeing Performance of NAND Flash Memory

In the process of testing NAND flash memories, testing to check the programming time, the reading time, and the erasing time can be performed efficiently and precisely. In addition, the selected blocks that fail to meet the specifications can be registered easily as bad blocks. Accordingly, the performance, i.e., the data transfer speed, of each NAND flash memory to be shipped from a factory can be controlled more precisely.

### (2) Shorter Testing Time

Conventionally, in operation of registering bad blocks, a wait time is set with a margin until input of the subsequent command, because it is assumed that there are blocks or chips having slower programming speeds. According to the NAND flash memory and the testing method of the embodiment, a busy wait time at the time of testing can be set as being defined by the specifications, so that the testing time can be shortened.

### (3) Improvement in Yield

A block is made to transit to the busy state after input of a command, and the block is sometimes fixed to a busy state. If this occurs in conventional cases, the subsequent blocks cannot receive any commands. Consequently, it is possible that the chip as a whole may be identified as a failure product. According to the NAND flash memory of the embodiment, such a selected block is registered as a bad block, and then the signal level of the R/B terminal is restored mandatorily to a ready state. Accordingly, the testing on the subsequent blocks can be conducted. Consequently, the yield of the chips can be improved.

In the embodiment, a NAND flash memory is used as an example nonvolatile semiconductor memory. There may be used not only a NAND flash memory but also various kinds of flash memories such as a NOR flash memory or an AND flash memory. In addition, a nonvolatile semiconductor memory that is not a flash memory may be used as long as the nonvolatile semiconductor memory allows a certain number of bad blocks at the time of shipment from a factory.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A nonvolatile semiconductor memory, comprising:
a memory cell array having a plurality of blocks which are erasing units respectively, each of the blocks including a plurality of memory cells; and
a peripheral circuit having a block control unit, the block control unit operating according to input signals from outside and controlling operation of the blocks,
wherein the peripheral circuit further includes:
a ready/busy control circuit which, in response to an output from the block control unit, outputs a busy signal during a period of operation implementation for a block selected from the blocks and which outputs a ready signal out of the period of the operation implementation for the selected block; and
a registration control unit which registers the selected block as a bad block, in the case that the ready/busy control circuit outputs a busy signal when the registration control unit receives a bad block identification command.

2. A nonvolatile semiconductor memory according to claim 1, wherein the ready/busy control circuit outputs a ready signal, after the registration control unit registers the selected block as a bad block.

3. A nonvolatile semiconductor memory according to claim 1, wherein the registration control unit identifies whether the internal operation is completed normally and registers the selected block as a bad block when the internal operation is identified as not completed normally, in the case that the ready/busy control circuit outputs a ready signal when the bad block identification command is received.

4. A nonvolatile semiconductor memory according to claim 3, wherein the registration control unit identifies whether the internal operation is completed normally and does not register the selected block as a bad block when the internal operation is identified as completed normally, in the case that the ready/busy control circuit outputs a ready signal when the bad block identification command is received.

5. A nonvolatile semiconductor memory according to claim 1, wherein the operation of the blocks is at least one of writing, reading or erasing.

6. A nonvolatile semiconductor memory according to claim 1, wherein the registration control unit permits input of the bad block identification command, even if the ready/busy control circuit outputs either a ready signal or a busy signal, in a test mode.

7. A nonvolatile semiconductor memory according to claim 1, wherein the bad block identification command is inputted to the registration control unit after a predetermined time period passes, after a command to execute the operation for the selected block is received.

8. A nonvolatile semiconductor memory according to claim 1, wherein the ready/busy control circuit makes an output terminal of the circuit high-level mandatorily after the registration control unit registers the selected block as a bad block.

9. A nonvolatile semiconductor memory according to claim 1, wherein the peripheral circuit further includes a row decoder having a row decoder block corresponding to the selected block, and the registration of the selected block disables subsequent selection of the selected block by the row decoder block.

10. A nonvolatile semiconductor memory according to claim 1, wherein, with registration of the selected block by the registration control unit, a flag data indicating a bad block is written in a predetermined page inside the selected block.

11. A nonvolatile semiconductor memory according to claim 1, wherein the memory cell array is a NAND flash memory array.

12. A method of testing a nonvolatile semiconductor memory, which is provided with a memory cell array having a plurality of blocks as erasing units including a plurality of memory cells respectively, and a peripheral circuit having a block control unit which operates according to input signals from outside and which controls operation of the blocks, comprising:
inputting an operation implementation command to execute operation for a block selected from the blocks of the nonvolatile semiconductor memory;
inputting a bad block identification command to the nonvolatile semiconductor memory after the operation implementation command is inputted, and identifying whether the interior of the nonvolatile semiconductor memory is in a ready state or in a busy state; and
registering the selected block as a bad block in the case that the interior of the nonvolatile semiconductor memory is identified as in a busy state.

13. A method of testing a nonvolatile semiconductor memory according to claim 12, wherein a ready state of the nonvolatile semiconductor memory is indicated, after the selected block is registered as a bad block.

14. A method of testing a nonvolatile semiconductor memory according to claim 12, further comprising:
identifying whether the internal operation is completed normally; and
registering the selected block as a bad block when the internal operation is identified as not completed normally, in the case that the interior of the nonvolatile semiconductor memory is identified as in a ready state when the bad block identification command is inputted.

15. A method of testing a nonvolatile semiconductor memory according to claim 14, wherein identifying whether the internal operation is completed normally and does not register the selected block as a bad block when the internal operation is identified as completed normally, in the case that the interior of the nonvolatile semiconductor memory is identified as in a ready state when the bad block identification command is inputted.

16. A method of testing a nonvolatile semiconductor memory according to claim 12, wherein the operation of the blocks is at least one of writing, reading or erasing.

17. A method of testing a nonvolatile semiconductor memory according to claim 12, wherein input of the bad block identification command is permitted, even if the interior of the nonvolatile semiconductor memory is in a ready state or in a busy state, in a test mode.

18. A method of testing a nonvolatile semiconductor memory according to claim 12, wherein the bad block identification command is inputted after a predetermined time period passes, after a command to execute the operation for the selected block is received.

19. A method of testing a nonvolatile semiconductor memory according to claim 12, wherein the registration of the selected block disables subsequent selection of the selected block by a row decoder block corresponding to the selected block, which is included is a row decoder provided in the peripheral circuit.

20. A method of testing a nonvolatile semiconductor memory according to claim 12, wherein, with the registration of the selected block, a flag data indicating a bad block is written in a predetermined page inside the selected block.
